(19) United States
(12) Patent Application Publication
(10) Pub. No.: US 2017/0369775 A1
(43) Pub. Date: Dec. 28, 2017

(54) PHOSPHOR, METHOD OF PRODUCING SAME, AND LIGHT-EMITTING DEVICE

(71) Applicant: Panasonic Corporation, Osaka (JP)

(72) Inventors: KOJIRO OKUYAMA, Nara (JP); YOSHIHISA NAGASAKI, Osaka (JP); TAKASHI OHBAYASHI, Osaka (JP)

(21) Appl. No.: 15/615,858

(22) Filed: Jun. 7, 2017

(30) Foreign Application Priority Data
Jun. 24, 2016 (JP) 2016-125672

(51) Int. Cl. C09K 11/62; H01L 33/50; C09K 11/77; C09K 11/70; C09K 11/64; H01L 51/50; C09K 11/08

(52) U.S. Cl. CPC C09K 11/621; H01L 51/50; H01L 33/502; C09K 11/0822; C09K 11/701; C09K 11/641; C09K 11/7716

(57) ABSTRACT

A phosphor includes, as a main component, a compound represented by a general formula (3-a)YO_{3/2}.aCeO_{3/2}.(5-b)AlO_{3/2}.bGaO_{3/2}.cKO_{1/2}.dPO_{5/2}, where a, b, c and d satisfy 0.12≦a≦0.18, 1.50≦b≦3.00, 0.01≦c≦0.08, and 0.01≦d≦0.08.

### BACKGROUND

### 1. Technical Field

The present disclosure relates to a phosphor, a method of producing the same, and a light-emitting device using a phosphor.

### 2. Description of the Related Art

The compound represented by the chemical formula Y₃Al₅O₁₂ is widely known under the name of yttrium aluminum garnet and has been used in solid-state lasers, translucent ceramics, and the like.

In particular, phosphors (YAG:Ce) in which cerium (Ce) ions serving as luminescent centers are added to yttrium aluminum garnet are known. It is known that YAG:Ce phosphors are excited by irradiation with corpuscular beams, such as electron beams, or electromagnetic waves, such as ultraviolet rays and blue light, and emit yellow to green visible light. Therefore, YAG:Ce phosphors are broadly used in various light-emitting devices (for example, refer to the specification of Japanese Patent No. 3503139; the specification of U.S. Pat. No. 6,812,500; and “Phosphor Handbook” edited by Keikoutaidougakukai, Ohmsha, Ltd., p. 12, pp. 237-238, pp. 268-278, and p. 332).

Yttrium aluminum garnet-type phosphors are used as yellow phosphors in various light-emitting devices. Typical examples of such light-emitting devices include a white light-emitting diode (LED) in which a blue LED and a yellow phosphor are combined, a projector using a blue laser diode (LD) and a phosphor, an illumination light source using a blue-violet LD or blue-violet LED and a phosphor, and a liquid crystal display (LCD) provided with an LED backlight.

In particular, an illumination light source including a blue-violet LD or blue-violet LED, a blue phosphor, and a yellow phosphor is able to achieve high color rendering.

### SUMMARY

One non-limiting and exemplary embodiment provides a phosphor which can have high external quantum efficiency.

In one general aspect, the techniques disclosed here feature a phosphor represented by a general formula (3-a)YO_{3/2}.aCeO_{3/2}.(5-b)AlO_{3/2}.bGaO_{3/2}.cKO_{1/2}.dPO_{5/2}, where a, b, c and d satisfy 0.12≦a≦0.18, 1.50≦b≦3.00, 0.01≦c≦0.08, and 0.01≦d≦0.08.

A phosphor according to one aspect of the present disclosure can have high external quantum efficiency.

It should be noted that general or specific embodiments may be implemented as a phosphor, a device, a system, a method, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a graph showing the relationship between the addition amount (a) of Ce in the general formula and the external quantum efficiency and the relationship between the addition amount (a) of Ce in the general formula and the chromaticity, with regard to phosphor samples 9 to 11 of Example and phosphor samples 1 and 2 of Comparative Example;

FIG. 2 is a graph showing the relationship between the addition amount (b) of Ga in the general formula and the external quantum efficiency and the relationship between the addition amount (b) of Ga in the general formula and the chromaticity, with regard to phosphor samples 10 and 16 to 21 of Example and phosphor samples 3 and 4 of Comparative Example;

FIG. 3 is a graph illustrating the relationship between the Ga concentration and the luminescent chromaticity and the relationship between the Ga concentration and the absorptance for blue-violet light, with regard to YAG:Ce phosphors;

FIG. 4 is a graph illustrating the relationship between the Ce concentration and the luminescent chromaticity and the relationship between the Ce concentration and the internal quantum efficiency, with regard to YAG:Ce phosphors; and

FIG. 5 is a graph showing an example of the relationship between the oxygen partial pressure in the firing atmosphere and the internal quantum efficiency of phosphors.

### DETAILED DESCRIPTION

The knowledge on which the present disclosure is based will be described below.

In YAG:Ce phosphors, the absorptance for blue-violet light with a wavelength of about 405 nm is lower than the absorptance for blue light with a wavelength of about 450 nm. Therefore, in the case where blue-violet light is used as excitation light, it is difficult to enhance the external quantum efficiency, which is the product of the absorptance for excitation light (hereinafter, may be simply abbreviated as the “absorptance”) and the internal quantum efficiency.

When aluminum (Al) is partially replaced by gallium (Ga) in a YAG:Ce phosphor, the absorptance for blue-violet light can be enhanced. However, increasing the addition amount of Ga shifts the peak wavelength of light emitted from the phosphor toward the shorter wavelength side, and it is not possible to obtain good yellow light emission, which is a problem.

The present inventors conducted studies on the absorptance for blue-violet light (wavelength: 405 nm) in YAG:Ce phosphors to which Ga is added and on the chromaticity of light emitted from the YAG:Ce phosphors in Experiment 1. The procedure and results thereof will be described below.

In Experiment 1, a plurality of YAG:Ce phosphors represented by the general formula (3-a)YO_{3/2}.aCeO_{3/2}.(5-b)AlO_{3/2}.bGaO_{3/2} were produced by setting the addition amount (a) of Ce in the general formula to be 0.06 and the addition amount (b) of Ga in the general formula to be varied. The YAG:Ce phosphors were produced by firing mixtures prepared by mixing starting materials at predetermined ratios. The mixtures were fired in nitrogen gas which contained hydrogen gas (hydrogen gas content: 2%) at a temperature of 1,600° C. for 4 hours. Subsequently, the absorptance for blue-violet light and luminescent chromaticity of the resulting YAG:Ce phosphors were measured. In this experiment, regarding the chromaticity, the value x of the chromaticity coordinates in the XYZ colorimetric system of the International Commission on Illumination (CIE) was measured.

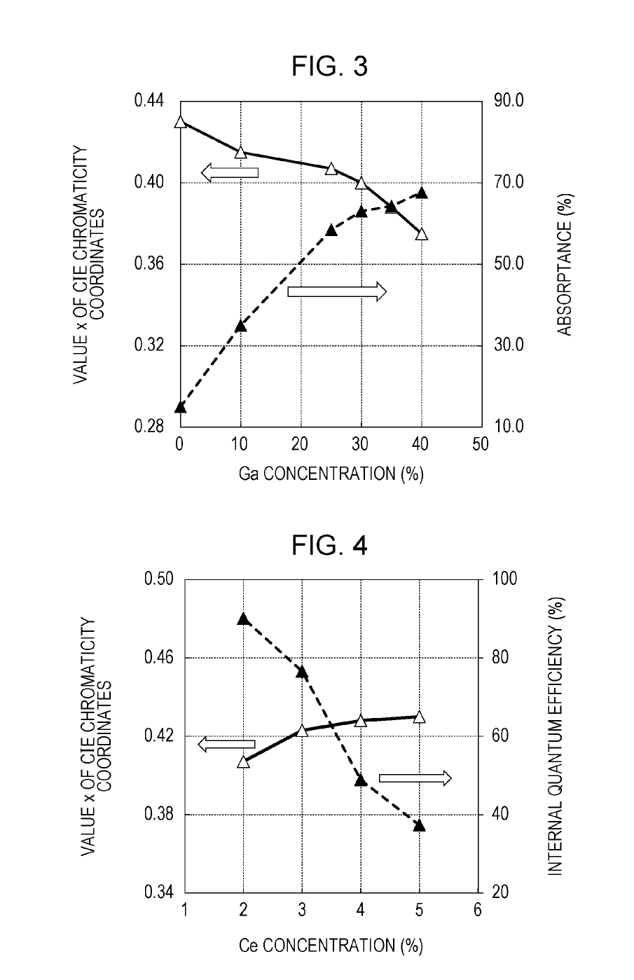

FIG. 3 is a graph illustrating the relationship between the Ga concentration and the luminescent chromaticity (value x) and the relationship between the Ga concentration and the absorptance for blue-violet light, with regard to the YAG:Ce phosphors. Note that the “Ga concentration” refers to the ratio (%) of the number of moles of Ga to the total number of moles of Al and Ga. Consequently, for example, when the Ga concentration is 30%, the addition amount (b) of Ga in the general formula is 1.5.

As is evident from FIG. 3, as the Ga concentration increases, the absorptance for excitation light increases, but the luminescent chromaticity (value x) decreases. That is, there is a trade-off relation between the absorptance and the chromaticity. When the chromaticity decreases, it may not be possible to obtain good yellow light emission in some cases.

Accordingly, the present inventors conducted further studies on the composition of a compound that can enhance the external quantum efficiency while securing the desired luminescent chromaticity and studies on the process therefor. As a result, it was found that, when the addition amount of Ce in a YAG:Ce phosphor is increased, it is possible to enhance the luminescent chromaticity.

The present inventors conducted studies on the relationship between the Ce concentration and the internal quantum efficiency and the relationship between the Ce concentration and the luminescent chromaticity, with regard to YAG:Ce phosphors in Experiment 2. The procedure and results thereof will be described below.

In Experiment 2, a plurality of YAG:Ce phosphors represented by the general formula (3-a)YO_{3/2}.aCeO_{3/2}.(5-b)AlO_{3/2}.bGaO_{3/2} were produced by setting the addition amount (b) of Ga in the general formula to be 1.25 and the addition amount (a) of Ce in the general formula to be varied. The YAG:Ce phosphors were produced by firing mixtures prepared by mixing starting materials at predetermined ratios. The firing was performed under the same conditions as those in Experiment 1. Subsequently, the internal quantum efficiency and luminescent chromaticity of the resulting YAG:Ce phosphors were measured.

FIG. 4 is a graph illustrating the relationship between the Ce concentration and the luminescent chromaticity and the relationship between the Ce concentration and the internal quantum efficiency, with regard to YAG:Ce phosphors. The “Ce concentration” refers to the ratio (%) of the number of moles of Ce to the total number of moles of Y and Ce. Consequently, for example, when the Ce concentration is 4%, the addition amount (a) of Ce in the general formula is 0.12.

As is evident from FIG. 4, as the Ce concentration increases, the luminescent chromaticity of phosphors increases. This result shows that, in YAG:Ce phosphors to which Ga is added, by increasing the Ce concentration, it is possible to obtain yellow light emission. However, as the Ce concentration increases, the internal quantum efficiency decreases. That is, there is a trade-off relation between the luminescent chromaticity and the internal quantum efficiency. Therefore, although the absorptance can be increased by adding Ga, it is difficult to improve the external quantum efficiency, which is the product of the absorptance and the internal quantum efficiency.

Under the circumstances, the present inventors conducted further studies and found that when potassium (K) and phosphorus (P) are further added to a YAG:Ce phosphor having a high Ce concentration, it is possible to suppress a decrease in the internal quantum efficiency, thus devising a phosphor according to the present disclosure. According to one aspect of the present disclosure, it is possible to provide a yellow light-emitting phosphor which can have high external quantum efficiency for blue-violet excitation light.

Aspects of the present disclosure are based on the above-described knowledge and can be summarized below.

A phosphor according to one aspect of the present disclosure includes, as a main component, a compound represented by the general formula (3-a)YO_{3/2}.aCeO_{3/2}.(5-b)AlO_{3/2}.bGaO_{3/2}.cKO_{1/2}.dPO_{5/2}. In the general formula, a, b, c and d satisfy 0.12≦a≦0.18, 1.50 b≦3.00, 0.01≦c≦0.08, and 0.01≦d≦0.08.

A light-emitting device according to another aspect of the present disclosure includes the phosphor and an excitation light source which emits first light having a peak wavelength of 380 to 420 nm. The phosphor absorbs part of the first light from the excitation light source and thereby emits second light having a longer wavelength than the first light.

A method for producing a phosphor according to another aspect of the present disclosure is a method for producing a phosphor. The phosphor includes, as a main component, a compound represented by the general formula (3-a)YO_{3/2}.aCeO_{3/2}.(5-b)AlO_{3/2}.bGaO_{3/2}.cKO_{1/2}.dPO_{5/2} (0.12≦a≦0.18, 1.50≦b≦3.00, 0.01≦c≦0.08, 0.01≦d≦0.08). This method includes (i) preparing a mixture which includes starting materials for the phosphor and (ii) firing the mixture. The firing of the mixture is performed in an atmosphere with an oxygen partial pressure of 10⁻⁶ to 10⁻³ atm.

The mixture may include, as a reaction accelerator, a fluorine-containing compound.

### First Embodiment

A phosphor according to a first embodiment will be described below.

A phosphor according to this embodiment includes, as a main component, a compound represented by the general formula (3-a)YO_{3/2}.aCeO_{3/2}.(5-b)AlO_{3/2}.bGaO_{3/2}.cKO_{1/2}.dPO_{5/2}. In the general formula, a, b, c and d satisfy 0.12≦a≦0.18, 1.50 b≦3.00, 0.01≦c≦0.08, 0.01≦d≦0.08. In this specification, a, b, c, and d in the general formula refer to the addition amounts of Ce, Ga, K, and P, respectively.

Note that the phrase “includes, as a main component” means that, for example, the compound is included in an amount of 70% by weight or more, or desirably 90% by weight or more, relative to the entire phosphor. The phosphor according to this embodiment may include, in addition to the compound represented by the general formula, an additive, an impurity, or the like.

When the addition amount (b) of Ga in the general formula is 1.50 or more, it is possible to enhance the absorptance for blue-violet light. On the other hand, when the addition amount (b) of Ga in the general formula is 3.00 or less, it is possible to suppress a decrease in luminescent chromaticity. When the addition amount (a) of Ce in the general formula is 0.12 or more, it is possible to suppress a decrease in luminescent chromaticity due to addition of Ga, and yellow light emission can be realized. When the addition amount (a) of Ce in the general formula is 0.18 or less, it is possible to suppress a decrease in internal quantum efficiency due to segregation of Ce and the like. Furthermore, when the addition amount (c) of K and the addition amount (d) of P are each in a range of 0.01 to 0.08, the Ce concentration distribution can be made more uniform, and therefore, internal quantum efficiency can be enhanced.

Accordingly, the phosphor according to this embodiment can be used as a yellow phosphor which has high external quantum efficiency for blue-violet excitation light.

### <Method of Producing Phosphor>

An example of a method of producing the phosphor according to this embodiment will be described below. Note that as long as the phosphor according to this embodiment includes, as a main component, the compound represented by the formula described above, the production method therefor is not limited to that described below.

As starting materials for the phosphor, compounds which are convertible to oxides by firing, such as high purity (purity 99% or more) hydroxides, carbonates, and nitrates, or high purity (purity 99% or more) oxides can be used. In order to accelerate the reaction, a fluorine (F)-containing compound (e.g., a fluoride, such as aluminum fluoride) may be added. The amount of the fluoride added is not particularly limited. The amount of the fluoride may be, for example, 0.1 to 10 mole percent (e.g., 1 mole percent) relative to the phosphor.

The starting materials are mixed to obtain a mixed powder. As a method for mixing starting materials, wet mixing in a solution or dry mixing of dry powders may be used. In the mixing method, a ball mill, a medium agitation mill, a planetary mill, a vibration mill, a jet mill, a V-type mixer, an agitator, or the like, which is normally used industrially, can be used.

Subsequently, by firing the mixed powder, a phosphor according to this embodiment is obtained.

The firing of the mixed powder is performed in an atmosphere containing oxygen. The oxygen partial pressure (hereinafter, referred to as the “oxygen partial pressure in the firing atmosphere”) at the firing temperature is, for example, set to be 10⁻⁶ to 10⁻³ atm. A mixed gas containing carbon dioxide gas may be used as the atmospheric gas. In the case where a mixed gas containing nitrogen gas, hydrogen gas, and carbon dioxide gas is used, the content of hydrogen gas may be more than 0% and less than or equal to 5% by volume and the content of carbon dioxide gas may be more than 0% and less than or equal to 50% by volume relative to the entire mixed gas. The oxygen partial pressure can be adjusted by the mixing ratio in the mixed gas. The firing temperature may be set, for example, to be in a range of 1,500° C. to 1,700° C. The firing time may be, for example, in a range of 1 to 50 hours.

A furnace which is normally used industrially can be used in the firing. For example, a continuous electric furnace such as a pusher furnace, or a batch-type electric furnace or gas furnace may be used.

The phosphor powder which has been fired may be pulverized again by using a ball mill, a jet mill, or the like, and furthermore, may be optionally washed or classified. Thereby, it is possible to adjust the particle size distribution and fluidity of the phosphor powder.

In the method described above, the oxygen partial pressure in the firing atmosphere is set to be higher than that in existing methods. Thereby, it is possible to suppress a decrease in internal quantum efficiency due to addition of Ce. The reason for this will be described below.

In existing methods of producing a YAG:Ce phosphor, when a mixed powder is fired in a chamber, a mixed gas containing nitrogen gas and hydrogen gas is used as an atmospheric gas, or firing is performed in a vacuum. Accordingly, the atmosphere in the chamber does not substantially contain oxygen, and the oxygen partial pressure in the chamber is 10⁻¹⁰ atm or less.

The present inventors conducted studies and found that when a phosphor including Ce and Ga at relatively high concentrations is produced by the same method as the existing methods, there is a possibility that a phosphor having high internal quantum efficiency will not be obtained. It is believed that factors for this include the occurrence of crystal defects due to an oxygen deficiency caused by the firing and segregation of part of Ce without being replaced, a degradation in crystallinity due to sublimation of Ga from the mixed powder during the firing, and the like.

For example, in Experiment 2 described above, phosphors including Ce and Ga at relatively high concentrations were fired in nitrogen gas which contained hydrogen gas (hydrogen gas content: 2%). The oxygen partial pressure at the firing temperature was about 10⁻¹² atm. As a result, as shown in FIG. 4, as the Ce concentration increases, the internal quantum efficiency decreases markedly. The reason for this is believed to be that when the Ce concentration increases (e.g., to more than 3%), Ce is not effectively replaced, resulting in an increase in crystal defects.

In contrast, in the firing process according to this embodiment, by using oxygen-containing gas (e.g., carbon dioxide gas) as the atmospheric gas, the oxygen partial pressure in the atmosphere is increased, for example, to 10⁻⁶ atm or more. Thereby, the sublimation of Ga can be suppressed, and the oxygen deficiency can be decreased. Furthermore, by increasing the oxygen partial pressure and adding P and K, even when the Ce concentration increases, Ce and Y can be effectively replaced. Therefore, it is possible to more effectively suppress a degradation in crystallinity and a decrease in internal quantum efficiency due to crystal defects and the like.

### (Study on Oxygen Partial Pressure)

Regarding two phosphors A and B having different compositions, the relationship between the oxygen partial pressure in the firing atmosphere and the internal quantum efficiency of the phosphors was checked The procedure and results thereof will be described below.

The compositions of the phosphor A and the phosphor B are as follows:

Phosphor A: (3-a)YO_{3/2}.aCeO_{3/2}.(5-b)AlO_{3/2}.bGaO_{3/2}.cKO_{1/2}.dPO_{5/2}, where a=0.12, b=2.25, and c=d=0.01.

Phosphor B: (3-a)YO_{3/2}.aCeO_{3/2}.(5-b)AlO_{3/2}.bGaO_{3/2}.cKO_{1/2}.dPO_{5/2}, where a=0.06, and b=c=d=0.

The phosphor A is a phosphor of Example which includes Ce, Ga, K, and P. The phosphor B is a phosphor of Comparative Example in which the addition amount (a) of Ce in the general formula is small and which does not include any of Ga, K, and P.

First, mixed powders serving as starting materials for the phosphors A and B were prepared. A plurality of samples were obtained by firing the mixed powders, at different oxygen partial pressures in the atmosphere, at a temperature of 1,650° C. for 16 hours. In the firing process, a mixed gas containing nitrogen gas, hydrogen gas, and carbon dioxide gas was used as the atmospheric gas, and the mixing ratio of the gases was adjusted to obtain predetermined oxygen partial pressures. Subsequently, the internal quantum efficiency of the resulting samples of the phosphors A and B was measured.

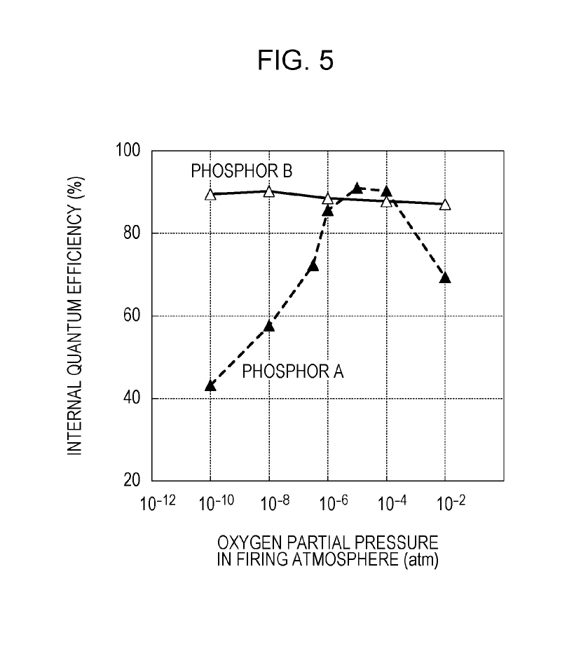

FIG. 5 is a graph showing an example of the relationship between the oxygen partial pressure in the firing atmosphere and the internal quantum efficiency of phosphors.

As shown in FIG. 5, in the phosphor B, high internal quantum efficiency can be obtained in a wide range of oxygen partial pressure (e.g., 10⁻² atm or less).

On the other hand, in the phosphor A, the internal quantum efficiency varies depending on the oxygen partial pressure in the firing atmosphere. When the oxygen partial pressure is 10⁻⁶ to 10⁻³ atm, higher internal quantum efficiency can be obtained. In particular, as is evident from the graph, by adjusting the oxygen partial pressure in a specific range (in this example, 10⁻⁶ to 10⁻⁴ atm), it is possible to achieve higher internal quantum efficiency than that of the phosphor B in which the addition amount of Ce is small. The reason for this is believed to be that by adding K and P to the phosphor and setting the oxygen partial pressure in the firing atmosphere to be 10⁻⁶ atm or more, Ce can be effectively replaced by firing. On the other hand, it is believed that when the oxygen partial pressure is either higher or lower than the range described above, Ce cannot be effectively replaced, resulting in an increase in crystal defects, and therefore, the internal quantum efficiency is decreased.

Note that the desirable range of oxygen partial pressure in the firing atmosphere is not limited to the example shown in FIG. 5. The range may vary depending on the composition of the phosphor (in particular, the addition amount (a) of Ce and the addition amount (b) of Ga in the general formula) and firing conditions, such as the firing temperature. It is believed that when the oxygen partial pressure is at least in the range of 10⁻⁶ to 10⁻³ atm, higher internal quantum efficiency can be obtained.

### (Light-Emitting Device)

The phosphor according to this embodiment has high external quantum efficiency, and therefore can constitute a highly efficient light-emitting device.

A light-emitting device according to this embodiment includes an excitation light source which emits first light and the phosphor. The phosphor absorbs part of the first light from the excitation light source and emits second light having a longer wavelength than the first light. The first light is, for example, blue-violet light having a peak wavelength in a range of 380 to 420 nm. The second light is, for example, yellow light having a peak wavelength in a range of 530 to 550 nm.

The excitation light source may be a semiconductor light-emitting element, such as a blue-violet LD or blue-violet LED. The structure of the light-emitting device other than the phosphor may be the same as that of an existing light-emitting device including a YAG:Ce phosphor.

Examples of the light-emitting device include an illumination light source including a blue-violet LD or blue-violet LED and the phosphor.

### EXAMPLES

Phosphor samples of Example and Comparative Example were produced and evaluated, which will be described below.

### <Production of Phosphor Samples>

Y₂O₃, Al₂O₃, Ga₂O₃, CeCl₃, K₂CO₃, and NH₄H₂PO₄ were used as starting materials, and AlF₃ was used as a reaction accelerator.

First, the starting materials were weighed so that predetermined compositions would be obtained, and wet mixing was performed in pure water by using a ball mill.

The resulting mixtures were dried, and then fired to obtain phosphors. In the firing process, a mixed gas containing hydrogen gas, carbon dioxide gas, and nitrogen gas was used as the atmospheric gas. The mixing ratio in the mixing gas was adjusted such that the content of hydrogen gas was more than 0% and less than or equal to 5% by volume and the content of carbon dioxide gas was more than 0% and less than or equal to 50% by volume relative to the entire mixed gas, and such that the oxygen partial pressure at the firing temperature was close to 10⁻⁴ atm. The firing temperature was set to be in a range of 1,500° C. to 1,700° C., and the firing time was set to be 16 hours.

Subsequently, the resulting phosphor powders were pulverized again by using a ball mill to adjust the particle size distribution. In such a manner, phosphor samples 1 to 22 were obtained. Regarding the phosphor samples, the addition amounts (a), (b), (c), and (d) of Ce, Ga, K, and P in the general formula (3-a)YO_{3/2}.aCeO_{3/2}.(5-b)AlO_{3/2}.bGaO_{3/2}.cKO_{1/2}.dPO_{5/2} are shown in Table.

### <Measurement of External Quantum Efficiency and Chromaticity>

The phosphor samples 1 to 22 were irradiated with blue-violet light with a wavelength of 405 nm serving as excitation light. The internal quantum efficiency of luminescence in the yellow range, the excitation light absorptance, and the luminescent chromaticity (value x of CIE chromaticity coordinates) in each phosphor sample were measured. The measurement was performed by using an absolute PL quantum yield spectrometer (manufactured by Hamamatsu Photonics, C9920). Furthermore, the external quantum efficiency was calculated from the internal quantum efficiency and the excitation light absorptance. The external quantum efficiency and the luminescent chromaticity of each phosphor sample are shown in Table.

Among all the phosphor samples, phosphor samples 9 to 22 correspond to Example having the composition ratio described in the first embodiment, and the others correspond to Comparative Example.

TABLE

| | | | | | | External | |
|---|---|---|---|---|---|---|---|
| | | Addition | Addition | Addition | addition | quantum | Luminescent |
| | | amount (a) | amount (b) | amount (c) | amount (d) | efficiency | chromaticity |
| | | of Ce | of Ga | of K | of P | (%) | (value x) |
| Comparative | 1 | 0.06 | 1.50 | 0.01 | 0.01 | 45 | 0.32 |
| Example | 2 | 0.36 | 1.50 | 0.01 | 0.01 | 32 | 0.39 |
| | 3 | 0.15 | 0 | 0.01 | 0.01 | 15 | 0.43 |
| | 4 | 0.15 | 4.50 | 0.01 | 0.01 | 52 | 0.30 |
| | 5 | 0.15 | 1.50 | 0 | 0.01 | 46 | 0.38 |
| | 6 | 0.15 | 1.50 | 0.20 | 0.01 | 54 | 0.39 |
| | 7 | 0.15 | 1.50 | 0.01 | 0 | 58 | 0.37 |
| | 8 | 0.15 | 1.50 | 0.01 | 0.20 | 42 | 0.35 |
| Example | 9 | 0.12 | 1.50 | 0.01 | 0.01 | 62 | 0.40 |
| | 10 | 0.15 | 1.50 | 0.01 | 0.01 | 64 | 0.42 |
| | 11 | 0.18 | 1.50 | 0.01 | 0.01 | 63 | 0.44 |
| | 12 | 0.18 | 3.00 | 0.08 | 0.08 | 65 | 0.41 |
| | 13 | 0.12 | 1.50 | 0.02 | 0.02 | 71 | 0.42 |
| | 14 | 0.12 | 2.00 | 0.02 | 0.02 | 73 | 0.40 |
| | 15 | 0.12 | 2.00 | 0.04 | 0.01 | 75 | 0.41 |
| | 16 | 0.15 | 1.50 | 0.02 | 0.02 | 68 | 0.43 |
| | 17 | 0.15 | 2.00 | 0.02 | 0.02 | 72 | 0.41 |
| | 18 | 0.15 | 2.50 | 0.02 | 0.02 | 70 | 0.40 |
| | 19 | 0.15 | 2.00 | 0.04 | 0.01 | 76 | 0.43 |
| | 20 | 0.15 | 2.00 | 0.04 | 0.02 | 75 | 0.42 |
| | 21 | 0.15 | 2.00 | 0.06 | 0.02 | 71 | 0.42 |
| | 22 | 0.18 | 2.00 | 0.06 | 0.02 | 65 | 0.43 |

As is evident from the results shown in Table, in phosphor samples 9 to 22 in which the conditions 0.12≦a≦0.18, 1.50 b≦3.00, 0.01≦c≦0.08, and 0.01≦d≦0.08 are satisfied, when blue-violet light is used as excitation light, the external quantum efficiency is high, and the chromaticity (value x: 0.40 or more) that is desirable as yellow light emission can be obtained.

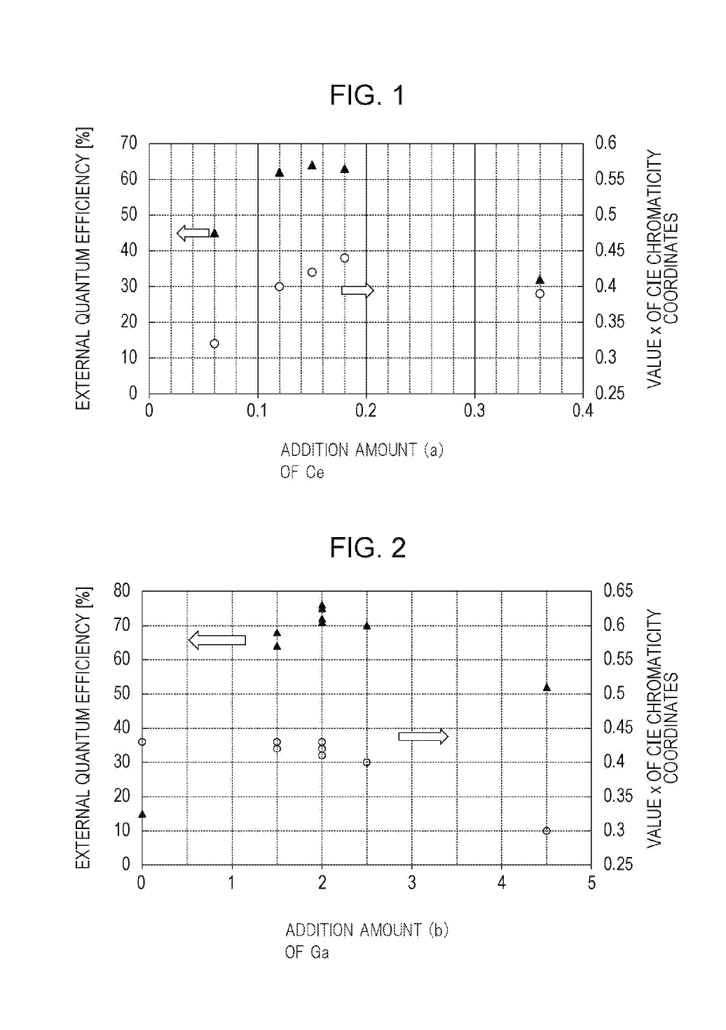

FIG. 1 is a graph showing the relationship between the addition amount (a) of Ce in the general formula and the external quantum efficiency and the relationship between the addition amount (a) of Ce in the general formula and the chromaticity, with regard to phosphor samples 1 and 2 of Comparative Example and phosphor samples 9 to 11 of Example. As is evident from FIG. 1, when the addition amount of Ce is in a range of 0.12 to 0.18, it is possible to achieve both desired luminescent chromaticity and high external quantum efficiency.

FIG. 2 is a graph showing the relationship between the addition amount (b) of Ga in the general formula and the external quantum efficiency and the relationship between the addition amount (b) of Ga in the general formula and the chromaticity, with regard to phosphor samples 3 and 4 of Comparative Example and phosphor samples 10 and 16 to 21 of Example. As is evident from FIG. 2, when the addition amount of Ga is in a range of 1.50 to 3.00, it is possible to enhance external quantum efficiency while suppressing a decrease in luminescent chromaticity.

The phosphor according to the embodiment of the present disclosure can be used in various light-emitting devices. For example, the phosphor can be used in illumination light sources and projectors using light-emitting diodes (LEDs) or laser diodes (LDs) and phosphors. Furthermore, the phosphor can be used in liquid crystal displays provided with an LED backlight, and sensors and sensitizers using phosphors.

What is claimed is:

1. A phosphor including, as a main component, a compound represented by a general formula (3-a)YO_{3/2}.aCeO_{3/2}.(5-b)AlO_{3/2}.bGaO_{3/2}.cKO_{1/2}.dPO_{5/2}, where a, b, c and d satisfy 0.12≦a≦0.18, 1.50 b≦3.00, 0.01≦c≦0.08, and 0.01≦d≦0.08.

2. The phosphor according to claim 1, including the compound in an amount of 70% by weight or more relative to the entire phosphor.

3. The phosphor according to claim 1, including the compound in an amount of 90% by weight or more relative to the entire phosphor.

4. The phosphor according to claim 1, wherein the phosphor absorbs light having a peak wavelength in a range of 380 to 420 nm to emit light having a peak wavelength in a range of 530 to 550 nm.

5. A light-emitting device comprising:
a phosphor including, as a main component, a compound represented by a general formula (3-a)YO_{3/2}.aCeO_{3/2}.(5-b)AlO_{3/2}.bGaO_{3/2}.cKO_{1/2}.dPO_{5/2}, where a, b, c and d satisfy 0.12≦a≦0.18, 1.50 b≦3.00, 0.01≦c≦0.08, and 0.01≦d≦0.08; and
an excitation light source which emits first light having a peak wavelength in a range of 380 to 420 nm,
wherein the phosphor absorbs part of the first light from the excitation light source to emit second light having a longer wavelength than the first light.

6. The light-emitting device according to claim 5, wherein the phosphor includes the compound in an amount of 70% by weight or more relative to the entire phosphor.

7. The light-emitting device according to claim 5, wherein the phosphor includes the compound in an amount of 90% by weight or more relative to the entire phosphor.

8. The light-emitting device according to claim 5, wherein the second light is light having a peak wavelength in a range of 530 to 550 nm.

9. A method for producing a phosphor, the phosphor including, as a main component, a compound represented by a general formula (3-a)YO_{3/2}.aCeO_{3/2}.(5-b)AlO_{3/2}.bGaO_{3/2}.cKO_{1/2}.dPO_{5/2}, where a, b, c and d satisfy 0.12≦a≦0.18, 1.50≦b≦3.00, 0.01≦c≦0.08, and 0.01≦d≦0.08, the method comprising:
preparing a mixture which includes starting materials for the phosphor; and
firing the mixture in an atmosphere with an oxygen partial pressure in a range of 10⁻⁶ to 10⁻³ atm.

10. The method according to claim 9, wherein the mixture includes, as a reaction accelerator, a fluorine-containing compound.

11. The method according to claim 9, wherein the phosphor includes the compound in an amount of 70% by weight or more relative to the entire phosphor.

12. The method according to claim 9, wherein the phosphor includes the compound in an amount of 90% by weight or more relative to the entire phosphor.

13. The method according to claim 9, wherein the phosphor absorbs light having a peak wavelength in a range of 380 to 420 nm to emit light having a peak wavelength in a range of 530 to 550 nm.
